(19) United States
(12) Patent Application Publication
(10) Pub. No.: US 2024/0347470 A1
(43) Pub. Date: Oct. 17, 2024

(54) BONDING STRUCTURE, METHOD OF MANUFACTURING THE SAME AND BONDING APPARATUS FOR MANUFACTURING THE SAME

(71) Applicant: SK hynix Inc., Gyeonggi-do (KR)

(72) Inventor: Byung Ho LEE, Gyeonggi-do (KR)

(21) Appl. No.: 18/465,982

(22) Filed: Sep. 13, 2023

(30) Foreign Application Priority Data
Apr. 12, 2023 (KR) 10-2023-0048051

(51) Int. Cl. H01L 23/544; H01L 21/68

(52) U.S. Cl. CPC H01L 23/544; H01L 21/682; H01L 2223/54426

(57) ABSTRACT

A bonding structure may include a first wafer, a second wafer, at least one first alignment key and a second alignment key. The first wafer may include first bonding pads. The second wafer may include second bonding wafers bonded to the first bonding pads. The first alignment key may be provided to the first wafer. The first alignment key may have a temporary magnetism by an induced current. The second alignment key may be provided to the second wafer. The second alignment key may correspond to the first alignment key.

### CROSS-REFERENCES TO RELATED APPLICATION

The present application claims priority under 35 U.S.C. § 119(a) to Korean application number 10-2023-0048051, filed on Apr. 12, 2023, in the Korean Intellectual Property Office, which is incorporated herein by reference in its entirety.

### BACKGROUND

### 1. Technical Field

Various embodiments generally relate to a semiconductor fabrication technology, particularly, to a bonding structure, a method of manufacturing the same and a bonding apparatus for manufacturing the same.

### 2. Related Art

As a size of an electronic device has decreased over time, a size of each of dies (or chips) in a wafer has also reduced. Further, a plurality of dies may be stacked to form an assembly in accordance with needs for requiring a massive capacity of the electronic device.

In order to effectively assemble dies having a small size, a hybrid bonding technology for directly bonding a plurality of wafers has been considered.

The hybrid bonding may be referred to as a fusion bonding or a direct bonding. In the hybrid bonding, the dies or the wafers may be directly bonded to each other without any layer between the dies or the wafers.

The hybrid bonding may use wafers having passed through a wafer test. Thus, it may be required to accurately align the wafers or the dies with each other.

### SUMMARY

According to the disclosed embodiments, there is provided a bonding structure. The bonding structure may include a first wafer, a second wafer, at least one first alignment key and at least one second alignment key. The first wafer may include first bonding pads. The second wafer may include second bonding wafers bonded to the first bonding pads. The first alignment key may be provided to the first wafer. The first alignment key is configured to be magnetized by induced current flow in the first alignment key. The second alignment key may be provided to the second wafer. The second alignment key may correspond to the first alignment key.

In various embodiments, each of the first and second wafers comprises a scribe lane configured to define a plurality of dies.

For example, the first alignment key may be positioned in the scribe lane of the first wafer, and the second alignment key may be positioned in the scribe lane of the second wafer.

The second alignment key may have a temporary magnetism by the induced current.

In various embodiments, at least one of the first and second alignment keys may include a plurality of stacked alignment patterns. The plurality of stacked alignment patterns may have a coil shape with respect to a stack direction.

In various embodiments, the first and second alignment keys have a same structure. The first and second alignment keys may have opposite polarities, each other.

In other embodiments, the first and second alignment keys may have different structures. The first and second alignment keys may have the same polarity.

In other embodiments, an attractive force may be generated between the first alignment key and the second alignment key. A repulsive force may be generated between the first alignment key and the second alignment key.

In various embodiments, at least one of the first and second alignment keys comprises a plurality of alignment patterns sequentially stacked, a plurality of insulating interlayers interposed between the alignment patterns and a plurality of insulating interlayers interposed between the alignment patterns.

The alignment patterns may have gradually changed structures in the stacked direction of the alignment patterns.

In various embodiments, the bonding structure may include a plurality of first alignment keys and a plurality of second alignment keys.

The plurality of first alignment keys may be arranged in the scribe lane of the first wafer in a rule, and the plurality of second alignment keys may be arranged in the scribe lane of the second wafer in a rule.

According to other embodiments, there is provided a method of manufacturing a bonding structure. In the method of manufacturing the bonding structure, a first wafer and a second wafer may be provided. The first wafer may include a plurality of first bonding pads and a plurality of first alignment keys. The second wafer may include a plurality of second bonding pads and a plurality of second alignment keys. The first wafer may be loaded into a first bonding chuck. The second wafer may be loaded into a second bonding chuck facing the first bonding chuck. An induced current may be generated in at least one selected from the first alignment keys and any one selected from the second alignment keys corresponding to the selected first alignment key to generate an electromagnetic force in the selected first and second alignment keys. The first bonding pads of the first wafer and the second bonding pads of the second wafer may be hybrid-bonded to each other using the electromagnetic force of the first and second alignment keys.

In various embodiments, a reference voltage may be applied to the selected first and second alignment keys. And then, a voltage, which is different from the reference voltage, may be applied to the selected first and second alignment keys, to generate the magnetic force at the selected first and second alignment keys.

In various embodiments, the reference voltage may be applied to the selected first and second alignment keys. And then, a first voltage, which is different from the reference voltage, may be applied to the selected first alignment key to provide a first induced current for generating a magnetic force having a first polarity to the selected first alignment key. A second voltage, which is different from the reference voltage and the first voltage, may be applied to the selected second alignment key to provide a second induced current for generating a magnetic force having a second polarity, which is different from the first polarity, to the selected second alignment key.

In other embodiments, the first and second wafers may comprise a plurality of dies including multi-layers conductive patterns and a scribe lane configured to define the dies.

For example, the first alignment keys may be positioned in the scribe lane of the first wafer, and the first wafer may comprise a plurality of alignment patterns formed simultaneously with the conductive patterns in the dies of the first wafer.

For example, the second alignment keys may be positioned in the scribe lane of the second wafer, and the second wafer may comprise a plurality of alignment patterns formed simultaneously with the conductive patterns in the dies of the second wafer.

According to other embodiments, there is provided an apparatus for manufacturing a bonding structure. The apparatus may include a process chamber, a first bonding chuck, a second bonding chuck and a magnetic force provider. The first bonding chuck may be arranged in a lower region of the process chamber. The first bonding chuck may include a first wafer-holding surface. The second bonding chuck may be arranged in an upper region of the process chamber to face the first bonding chuck. The second bonding chuck may include a second wafer-holding surface facing the first wafer-holding surface. The magnetic force provider may be provided to at least one of the first and second wafer-holding surfaces. The magnetic force provider may provide a part of a plurality of alignment keys of a wafer, which may be loaded into the first and second holding surfaces, with an induced current.

In various embodiments, the alignment keys may be arranged in a scribe lane of the wafer in a rule, and the magnetic force generators may correspond to a part of the alignment keys selected from the alignment keys.

In various embodiments, the bonding apparatus may further comprise a voltage generator.

For example, the voltage generator may be configured to provide the magnetic force generators with a reference voltage and first and second voltages different from the reference voltage.

According to other embodiments, the bonding pads of the wafer may be accurately aligned with each other using the temporarily magnetized alignment keys by the induced current.

Further, the alignment key may be formed by previously used processes without an additional process. The alignment key may be temporarily magnetized by the induced current so that an electrical problem by the magnetism of the alignment key may not be generated in other processes besides the bonding process.

### BRIEF DESCRIPTION OF THE DRAWINGS

FIG. 1 is a perspective view illustrating a bonding structure in accordance with various embodiments;

FIG. 2 is an enlarged plan view of a portion “A” in FIG. 1;

FIG. 3 is a plan view illustrating a pattern block in accordance with other embodiments;

FIG. 4 is an enlarged plan view illustrating an alignment key in FIG. 3;

FIG. 5 is a cross-sectional view taken along a line V-V′ in FIG. 3 illustrating the pattern block;

FIG. 6 is a perspective view illustrating an alignment key in accordance with still other embodiments;

FIG. 7 is a plan view illustrating a die with an alignment key in accordance with various embodiments;

FIG. 8 is a perspective view illustrating an alignment method of wafers in a bonding structure in accordance with other embodiments;

FIG. 9 is a cross-sectional view illustrating a bonding structure for explaining a bonding method of wafers in accordance with still other embodiments;

FIG. 10 is a flow chart illustrating a method of manufacturing a pattern block in accordance with various embodiments;

FIG. 11 is a perspective view illustrating wafers with an alignment key having different structures in accordance with other embodiments;

FIGS. 12 to 14 are cross-sectional views illustrating a method of bonding wafers using a repulsive force between alignment keys in accordance with still other embodiments;

FIG. 15 is a cross-sectional view illustrating a wafer bonding apparatus in accordance with various embodiments;

FIG. 16 is a plan view illustrating a wafer-holding surface in accordance with other embodiments;

FIG. 17 is a plan view illustrating a first wafer-holding surface in accordance with still other embodiments;

FIG. 18 is a plan view illustrating a second wafer-holding surface in accordance with various embodiments;

FIG. 19 is a flow chart illustrating a method of applying a magnetic force to an alignment key in accordance with other embodiments; and

FIG. 20 is a perspective view illustrating an alignment key in accordance with still other embodiments.

FIG. 21 is a schematic view of a system that includes a semiconductor die assembly configured in accordance with various embodiments.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described. On the contrary, the technology is intended to cover all modifications, equivalents, and alternatives falling within the scope of the technology.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the scope of the present invention.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and scope of the present invention.

In one embodiment of the present disclosure, there is provided a magnetized alignment key. In one embodiment of the present disclosure, there is provided improved hybrid bonding with reduced bonding failure between wafers or dies.

The magnetized alignment key can be achieved by changing a structure of the alignment key. In one example, the alignment key may include a coil-shape.

Further, a magnetization of the alignment key can also be achieved by a wafer bonding apparatus configured to provide voltages to the alignment key.

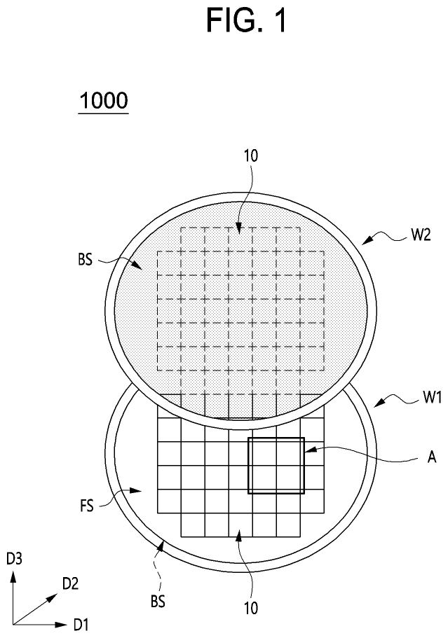

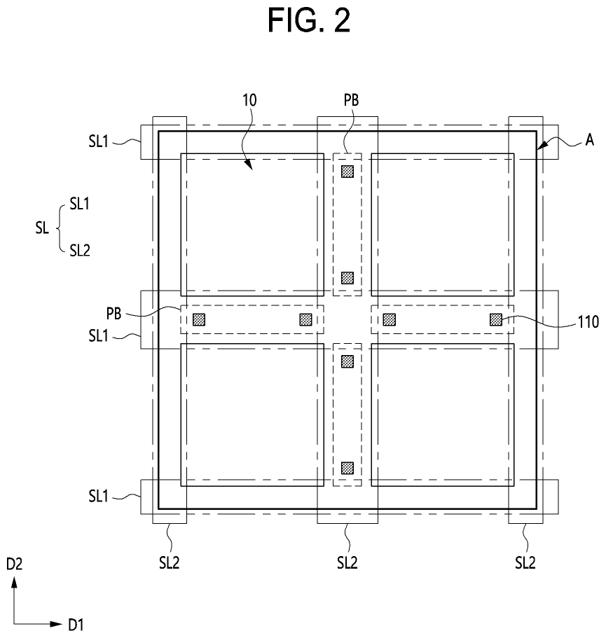

FIG. 1 is a perspective view illustrating a bonding structure in accordance with various embodiments and FIG. 2 is an enlarged plan view of a portion “A” in FIG. 1.

Referring to FIGS. 1 and 2, a bonding structure 1000 may include a first wafer W1 and a second wafer W2. Each of the first wafer W1 and the second wafer W2 may include a surface parallel to a first direction D1 and parallel to a second direction D2. A stack direction of the first and second wafers W1 and W2 may correspond to a third direction D3. For example, the first wafer W1 and the second wafer W2 may each include a first surface FS and a second surface BS parallel to the first and second directions D1 and D2, respectively. The first and second wafers W1 and W2 may be stacked to where the first surfaces FS of both the first and second wafers W1 and W2 face each other, along the stack direction D3, but the present disclosure is not limited thereto.

Each of the first and second wafers W1 and W2 may include a plurality of dies 10. For example, at least one of the first and second wafers W1 and W2 may include at least one or more of a silicon substrate, a silicon-on-insulator (SOI) substrate, a germanium substrate and a compound semiconductor substrate.

Each of the dies 10 may be referred to as a chip. For example, at least one of the dies 10 may include a semiconductor integrated circuit such as for example a plurality of memory cells, various control circuits, passive circuit elements, etc. For example, the semiconductor integrated circuit of the die may be formed on the first surface FS of the first and second wafers W1 and W2. For example, the semiconductor integrated circuit may include multi-level interconnections for connecting among the plurality of memory cells, various control circuits and passive circuit elements.

In some embodiments, at least one of the first and second wafer W1 and W2 may be formed by a front end of line (FEOL) process and a back end of line (BEOL) process.

For example, the FEOL process may include a process for forming the semiconductor integrated circuit. The BEOL process may include a process for connecting the integrated circuits with each other after the FEOL process.

Further, the first and second wafers W1 and W2 may be wafers that have passed a test process after the BEOL process.

The first and second wafers W1 and W2 may include scribe lane(s) SL configured to define the plurality of dies 10, respectively.

In some embodiments, the scribe lane SL of at least one of the first and second wafers W1 and W2 may include a plurality of first line regions SL1 and a plurality of second line regions SL2. The first line regions SL1 may be extended in a direction parallel to the first direction D1. The second line regions SL2 may be extended in a direction parallel to the second direction D2. The plurality of dies 10 may be defined in a matrix shape by the scribe lane SL including the first line regions SL1 and the second line region SL2.

The scribe lane SL may include at least one pattern block PB. In various embodiments, the scribe lane SL may include a plurality of pattern blocks PB. The plurality of pattern blocks PB may be provided to the first line regions SL1 and the second line region SL2. At least one of the pattern blocks PB may include a plurality of dummy patterns, such as, a plurality of alignment keys and a plurality of test patterns. The plurality of dummy patterns may be formed together with the multi-level interconnects in the die 10.

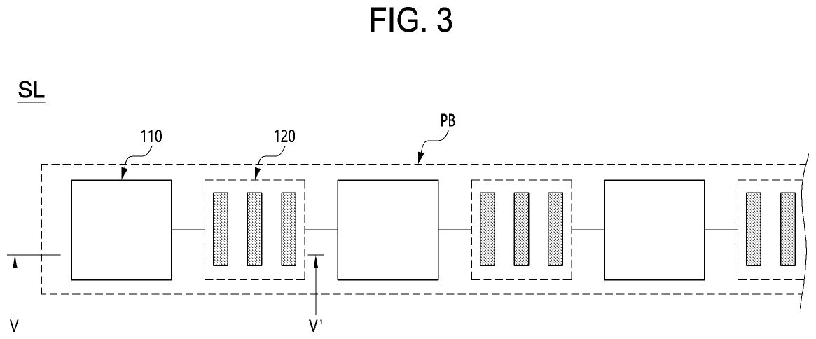

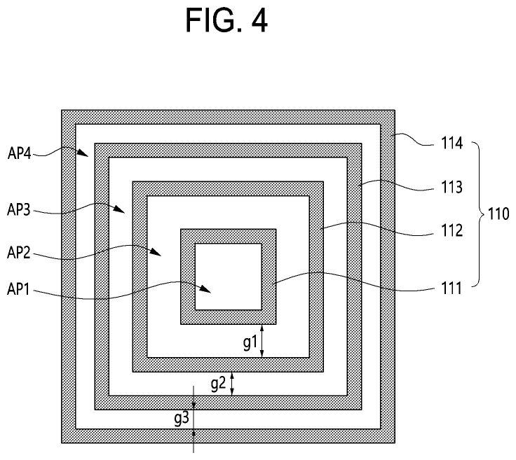

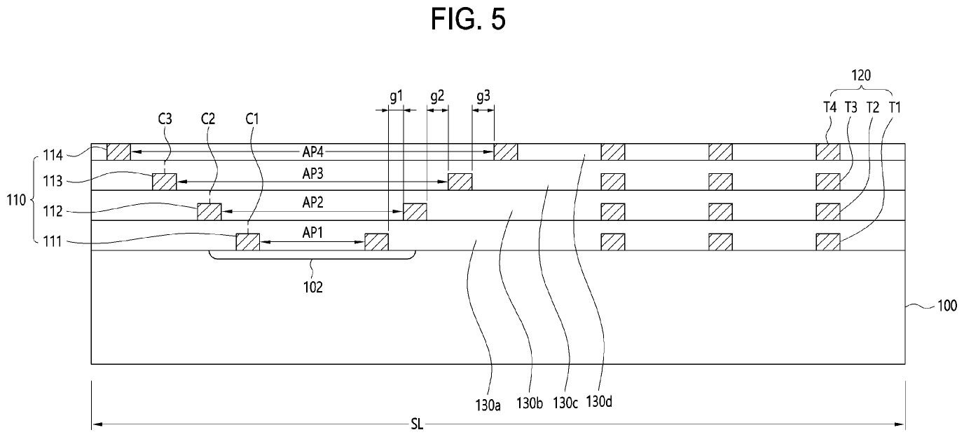

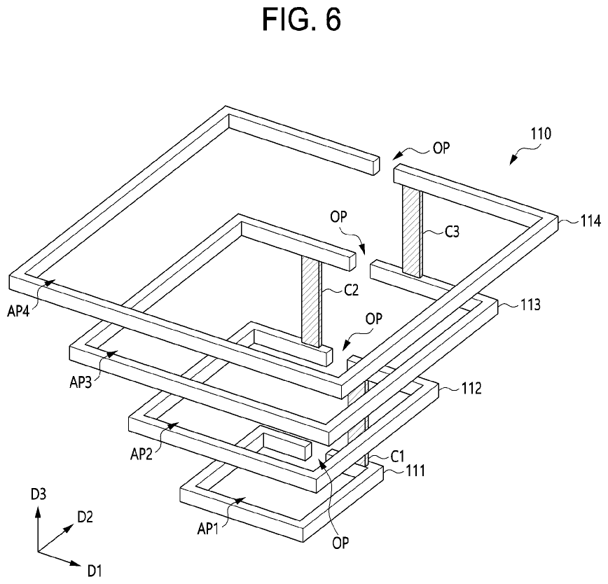

FIG. 3 is a plan view illustrating a pattern block in accordance with various embodiments, FIG. 4 is an enlarged plan view illustrating an alignment key in FIG. 3, FIG. 5 is a cross-sectional view taken along a line V-V′ in FIG. 3 illustrating the pattern block, and FIG. 6 is a perspective view illustrating an alignment key in accordance with various embodiments.

Referring to FIGS. 3 to 6, the scribe lane SL may include at least one pattern block PB. At least one alignment key 110 and at least one test pattern test pattern 120 may be arranged on the pattern block PB.

The alignment key 110 and the test pattern 120 may be formed in the pattern block PB wherever the plurality of memory cells, various control circuits, passive circuit elements and the multi-level interconnects are formed in the die.

In one example, the alignment key 110 may have a multi-layered structure similar to the multi-level interconnects of the integrated circuit. The alignment key 110 may have for example a coil shape with respect to a selected direction in order to generate magnetism when a current is applied.

In other embodiments, the alignment key 110 may include a plurality of stacked alignment patterns. Each of the alignment patterns may be formed simultaneously with the multi-level interconnects of the integrated circuit. The alignment patterns in the alignment key 110 may be vertically spaced apart from each other by a uniform gap or a uniform distance. Thus, a pattern error may be predicted based on a gap between a previous alignment pattern formed in a previous process and a present alignment pattern formed in a present process.

In other embodiments, as shown in FIG. 4, the alignment key 110 may include at least one first alignment pattern 111, at least one second alignment pattern 112, at least one third alignment pattern 113 and at least one fourth alignment pattern 114. The first to fourth alignment patterns 111-114 may have a planar frame shape, respectively. Shapes of the first to fourth alignment patterns 111-114 may be substantially same. In contrast, the first to fourth alignment patterns 111-114 may have different sizes. For example, as shown in FIG. 6, the first to fourth alignment patterns 111-114 may be sequentially stacked and connected with each other to form the coil-shaped alignment key 110.

The sizes of the first to fourth alignment patterns 111-114 may gradually increase or decrease from the first alignment pattern 111 to the fourth alignment pattern 114. A stack direction of the alignment patterns 111-114 may be a direction substantially perpendicular to an upper surface of the wafer, i.e., the third direction D3 in FIG. 1 or the stack direction of the wafers.

In one example, the first alignment pattern 111 may be arranged on a surface of a semiconductor substrate 100 corresponding to the scribe lane SL. The first alignment pattern 111 may include a first window AP1 having a first size. In various embodiments, the semiconductor substrate 100 may be a bulk portion of the first wafer W1 or the second wafer W2. The first and second wafers W1 and W2 may include the semiconductor integrated circuit and a plurality of bonding pads on the semiconductor substrate 100. The bulk portion and the semiconductor substrate 100 may represent a surface before the semiconductor integrated circuit is formed or on which one portion of the semiconductor integrated circuit is formed. In one example, the first alignment pattern 111 may include a conductive material. The semiconductor substrate 100 corresponding to the scribe lane SL may include at least one conductive region 102 (as shown in FIG. 5). The first alignment pattern 111 may be electrically connected to the conductive region 102. The conductive region 102 may include an impurity region, a conductive line, a through silicon via (TSV) electrically connected to the conductive line, or a conductive terminal connected to the TSV which are the one portion of the semiconductor integrated circuit.

The second alignment pattern 112 may be arranged over the first alignment pattern 111. For example, the second alignment pattern 112 may include a second window AP2 having a second size larger than the first size. The first alignment pattern 111 may be positioned in the second window AP2 of the second alignment pattern 112. As shown in FIG. 4, a first gap g1 may be formed between the first alignment pattern 111 and the second alignment pattern 112. The second alignment pattern 112 may also include a conductive material.

The third alignment pattern 113 may be arranged over the second alignment pattern 112. For example, the third alignment pattern 113 may include a third window AP3 having a third size larger than the second size. The second alignment pattern 112 may be positioned in the third window AP3 of the third alignment pattern 113. A second gap g2 may be formed between the second alignment pattern 112 and the third alignment pattern 113. The third alignment pattern 113 may also include a conductive material.

The fourth alignment pattern 114 may be arranged over the third alignment pattern 113. For example, the fourth alignment pattern 114 may include a fourth window AP4 having a fourth size larger than the third size. The third alignment pattern 113 may be positioned in the fourth window AP4 of the fourth alignment pattern 114. A third gap g3 may be formed between the third alignment pattern 113 and the fourth alignment pattern 114. The fourth alignment pattern 114 may also include a conductive material.

The first to third gaps g1-g3 may be distances between the first to fourth alignment patterns 111-114 viewed from a plane. As mentioned above, changes of the first gap g1 between the first alignment pattern 111 and the second alignment pattern 112, the second gap g2 between the second alignment pattern 112 and the third alignment pattern 113 and the third gap g3 between the third alignment pattern 113 and the fourth alignment pattern 114 may be checked to determine whether conductive patterns for the multi-level connects in the die are normally formed (positioned) or not.

In various embodiments, the first to fourth alignment patterns 111-114 may include the same conductive material or different conductive materials. For example, the materials of the first to fourth alignment patterns 111-114 may depend on a material of a multi-level interconnect formed on a same level.

Further, the alignment key 110 including the first to fourth alignment patterns 111-114, may receive a voltage through an electrical contact end, and the alignment key 110 becomes temporarily magnetic during the time when current flows in the alignment patterns (that is the alignment key has a temporary magnetism which does not persist after current flow is terminated). The electrical contact end may be an end of the fourth alignment pattern 114 corresponding to an uppermost alignment key or the first alignment pattern 111 corresponding to a lowermost alignment key.

Since the alignment key 110 may include the coil shape, when the voltage is applied to the alignment key 110, the alignment key 110 becomes magnetic.

Further, as shown in FIG. 5, a first insulating interlayer 130a may be interposed between the first alignment pattern 111 and the second alignment pattern 112. A second insulating interlayer 130b may be interposed between the second alignment pattern 112 and the third alignment pattern 113. A third insulating interlayer 130c may be interposed between the third alignment pattern 113 and the fourth alignment pattern 114. A fourth insulating interlayer 130d may be formed on the third insulating interlayer 130c to expose a surface of the fourth alignment pattern 114.

In some embodiments, in order to provide the alignment key 110 with the coil shape, the alignment key 110 may further include at least one connection member configured to connect together adjacent alignment patterns and forming an up portion and a down portion of the alignment key.

Particularly, the alignment key 110 may include a first connection member C1, a second connection member C2 and a third connection member C3.

As illustrated in FIG. 6, the first connection member C1 may be physically and electrically connected between the first alignment pattern 111 and the second alignment pattern 112. The first connection member C1 may be positioned in the first insulating interlayer 130a.

The second connection member C2 may be physically and electrically connected between the second alignment pattern 112 and the third alignment pattern 113. The second connection member C2 may be positioned in the second insulating interlayer 130b.

The third connection member C3 may be physically and electrically connected between the third alignment pattern 113 and the fourth alignment pattern 114. The third connection member C3 may be positioned in the third insulating interlayer 130c.

At least one of the first to third connection members C1-C3 may include at least one contact extended in the stack direction D3.

Alternatively, at least one of the first to third connection members C1-C3 may include a contact and a wiring. The contact may be extended in the stack direction D3. The wiring may connect between the contact and an adjacent alignment pattern. Because the stacked alignment patterns may have the different sizes, the wiring may be connected to any one of the stacked alignment patterns. Thus, the alignment patterns 111-114 in the alignment key 110 may have the coli shape without any disconnection in the stack direction D3.

In some embodiments, at least one of the alignment patterns 111-114 may include an opening OP, as shown in FIG. 6. Thus, at least one of the alignment patterns 111-114 may have an opened frame structure or an opened curve structure.

For example, when the opening OP is provided to any one selected from the alignment patterns 111-114, a current or a voltage may be applied through a portion of the alignment pattern at one end of the opening OP. Because the alignment patterns 111-114 of the alignment key 110 may be connected with each other without the disconnection, the current and the voltage transmitted through the portion of the alignment pattern may be supplied to all of the alignment key 110 including the alignment patterns 111-114 and the connection members C1-C3.

In various embodiments, magnetism or an electromagnetic force (or magnetic force) may be proportional to a winding number of a coil. Thus, the current or the voltage may be provided to the uppermost or lowermost alignment pattern to reinforce the magnetic force. Further, the voltage may be applied to the alignment pattern at the one end of the opening OP to generate an induced current for generating the magnetism.

In other embodiments, in order to provide the alignment key 110 with the coil shape, each of the alignment patterns 111-114 may have the opened frame shape. Further, in order to secure an induced electromotive force, the voltage may be applied to the uppermost or the lowermost alignment pattern, i.e., the one end of the opening OP in the first alignment pattern 111 or the fourth alignment pattern 114.

Further, in order to form the coil-shaped alignment key 110, the third connection member C3 may be positioned between the other end of the opening OP in the fourth alignment pattern 114 and the other end of the opening OP in the third alignment pattern 113. The second connection member C2 may be positioned between the one end of the opening OP in the third alignment pattern 113 and the one end of the opening OP in the second alignment pattern 112. The first connection member C1 may be positioned between the other end of the opening OP in the second alignment pattern 112 and the one end of the opening OP in the first alignment pattern 111.

In other embodiments, the one end of the opening OP may correspond to the alignment pattern positioned left the opening OP and the other end of the opening OP may correspond to the alignment pattern positioned right the opening OP, by the present disclosure is not limited thereto.

Referring back to FIGS. 3 and 5, the test pattern group 120 may include at least one first test pattern T1, at least one second test pattern T2, at least one third test pattern T3 and at least one fourth test pattern T4.

The first test pattern T1 may be positioned on the semiconductor substrate 100 together with the first alignment pattern 111. The second test pattern T2 may be positioned on the first insulating interlayer 130a together with the second alignment pattern 112. The third test pattern T3 may be positioned on the second insulating interlayer 130b together with the third alignment pattern 113. The fourth test pattern T4 may be positioned on the third insulating interlayer 130c together with the fourth alignment pattern 114.

The first to fourth test patterns T1-T4 may be overlapped with each other. In order to test electrical characteristics of the integrated circuit, the first to fourth test patterns T1-T4 may be electrically connected with each other. Alternatively, the test pattern group 120 may be electrically connected to the adjacent alignment key 110.

The test pattern group 120 may include the plurality of the test patterns. The test patterns T1-T4 of the test pattern group 120 may be formed by processes substantially the same as those for forming the conductive layers of the semiconductor integrated circuit similarly to the alignment patterns 111-114.

In some embodiments, the test pattern group 120 may be electrically connected to at least one of the adjacent alignment keys 110.

In various embodiments, the alignment key 110 may be formed together with the test pattern group 120 in the pattern block PB, but the present disclosure is not limited thereto. For example, a plurality of alignment key 110 may be arranged in the pattern block PB without the test pattern group.

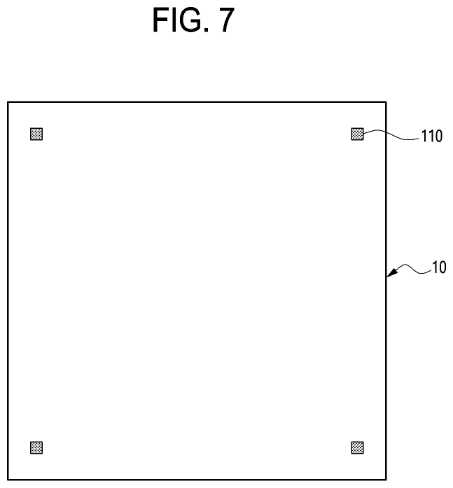

FIG. 7 is a plan view illustrating a die with an alignment key in accordance with various embodiments.

As shown in FIG. 7, the alignment key 110 may be positioned in the die 10. For example, at least one alignment key 110 may be positioned in an edge portion of the die 10. Thus, when a package, for example, a stack package may be manufactured, an alignment characteristic between the dies may be improved.

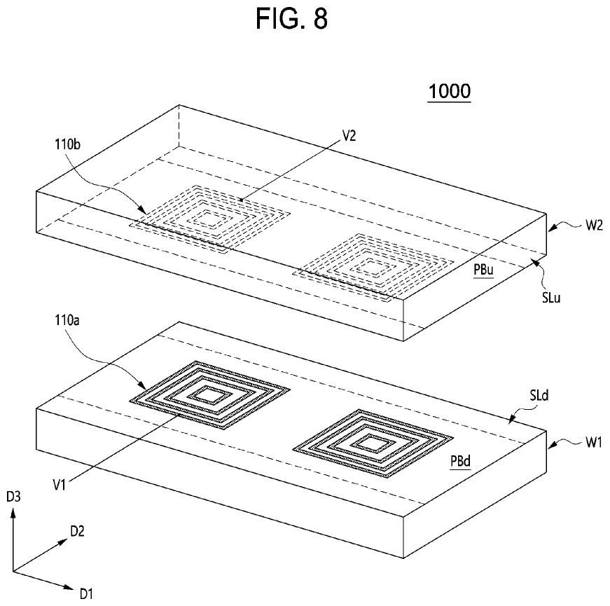

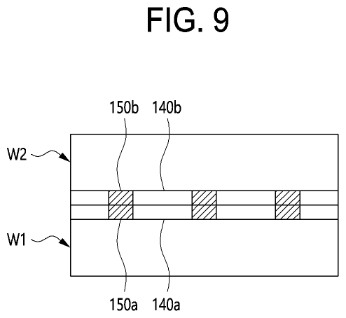

FIG. 8 is a perspective view illustrating an alignment method of wafers in a bonding structure in accordance with embodiments of the present disclosure, and FIG. 9 is a cross-sectional view illustrating a bonding structure for explaining a bonding method of wafers in accordance with these embodiments.

Referring to FIG. 8, a bonding structure 1000 may include a first wafer W1 and a second wafer W2. The first wafer W1 may include at least one first alignment key 110a. The second wafer W2 may include at least one second alignment key 110b.

As mentioned above, the first wafer W1 may include a scribe lane SLd and the second wafer W2 may include a scribe lane SLu. The first alignment key 110a may be formed in the scribe lane SLd and the second alignment key 110b may be formed in the scribe lane SLu. For example, the first alignment key 110a may be arranged in a pattern block PBd in the scribe lane SLd of the first wafer W1. The second alignment key 110b may be arranged in a pattern block PBu in the scribe lane SLu of the second wafer W2.

The first wafer W1 and the second wafer W2 may be stacked to face the first alignment key 110a and the second alignment key 110b to each other.

The first alignment key 110a and the second alignment key 110b may be used for checking an alignment between up and down conductive patters constituting of the semiconductor integrated circuit in the die 10. Further, the first alignment key 110a and the second alignment key 110b may be used for assisting an alignment between bonding pads of the first and second wafers W1 and W2.

In various embodiments, the first alignment key 110a of the first wafer W1 may have a structure substantially the same as a structure of the second alignment key 110b of the second wafer W2. In this case, the first alignment key 110a may be magnetized to a first polarity. The second alignment key 110b may be magnetized to a second polarity opposite to the first polarity.

Therefore, in one embodiment of the present disclosure, an attractive force may be generated between the first alignment key 110a and the second alignment key 110b to temporarily bond the first wafer W1 and the second wafer W2 to each other.

When the first alignment key 110a and the second alignment key 110b are accurately aligned with each other, as shown in FIG. 9, at least one first bonding pad 150a of the first wafer W1 and at least one second bonding pad 150b of the second wafer W2 may be determined to be aligned with each other.

The temporarily bonded first and second wafers W1 and W2 may be completely bonded to each other by a hybrid bonding process using a magnetic force between the first alignment key 110a and the second alignment key 110b.

In embodiments of the present disclosure, the temporarily bonding may be connecting by magnetic force and the hybrid bonding may be a physical attachment caused by the magnetic forced.

In one example, a first bonding insulation layer 140a and the first bonding pad 150a may be formed at a bonding surface of the first wafer W1. A second bonding insulation layer 140b and the second bonding pad 150b may be formed at a bonding surface of the second wafer W2.

The first bonding insulation layer 140a and the second bonding insulation layer 140b may be directly bonded to each other. And then, the first bonding pads 150a and the second bonding pads 150b may be directly bonded to each other. In one example, during the hybrid bonding process, external factors such as, heat and/or external force may be added.

Further, in FIG. 1, the bonding surfaces of the first and second wafers W1 and W2 may be the first surface FS on which the semiconductor integrated circuit may be formed. Alternatively, any one of the first and second surfaces FS and BS of the first wafer W1 and any one of the first and second surfaces FS and BS of the second wafer W2 may be bonded to each other.

In various embodiments, the alignment keys 110a and 110b and the bonding pads 150a and 150b may be positioned on a same surface, for example, the first surfaces FS of the wafers W1 and W2.

Alternatively, the alignment keys 110a and 110b and the bonding pads 150a and 150b may be positioned on different surfaces. For example, the alignment keys 110a and 110b may be positioned on the first surfaces FS of the wafers W1 and W2. The bonding pads 150a and 150b may be positioned on the second surfaces BS of the wafers W1 and W2. For example, the alignment key 110a and the bonding pad 150a may be spaced apart from each other with an insulating layer interposed therebetween. The alignment key 110b and the bonding pad 150b may be spaced apart from each other with an insulating layer interposed therebetween.

According to various embodiments, the bonding pads of the wafers may be accurately aligned with each other by the temporarily magnetized alignment keys to prevent or minimize a bonding error.

Further, the alignment key may have the temporary magnetism generated by the induced current only during the bonding process. In contrast, the alignment key may be operated as a conductive pattern without any magnetism in a process for forming the integrated circuit and a packaging process after the bonding process. Thus, the integrated circuit may not be affected by the magnetism of the alignment key so that an electromagnetic problem may be prevented.

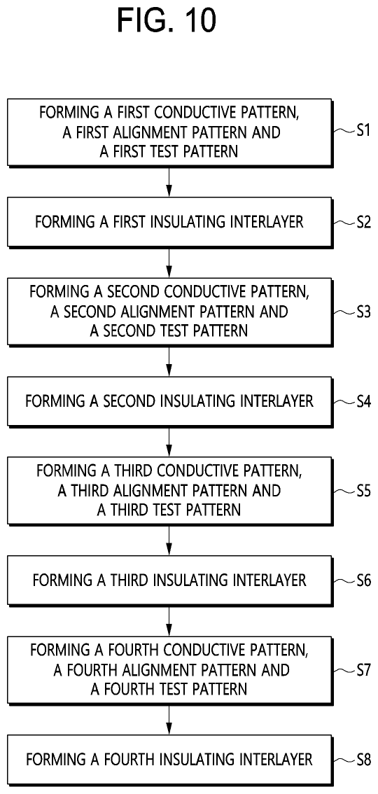

FIG. 10 is a flow chart illustrating a method of manufacturing a pattern block in accordance with example embodiments.

Referring to FIGS. 1 to 10, a first conductive layer may be formed on the semiconductor substrate 100. In operation S1, the first conductive layer may be patterned using a first mask to form a first conductive pattern of the semiconductor integrated circuit in a die region 10. Simultaneously, the first alignment pattern 111 and the first test pattern T1 may be formed in the scribe lane SL. For example, the first conductive pattern may include a gate electrode of the semiconductor integrated circuit.

In operation S2, the first insulating interlayer 130a may be formed on the semiconductor substrate 100 with the first conductive pattern, the first alignment pattern 111 and the first test pattern T1.

In operation S3, a second conductive layer may be formed on the first insulating interlayer 130a. The second conductive layer may be patterned using a second mask to form a second conductive pattern in the die region 10. Simultaneously, the second alignment pattern 112 and the second test pattern T2 may be formed in the scribe lane SL. As mentioned above, the second alignment pattern 112 may be formed at a region corresponding to the first window AP1 of the first alignment pattern 111. The second test pattern T2 may be electrically connected with the first test pattern T1. The second conductive pattern may include a first wiring or a bit line of the integrated circuit, not limited thereto.

In operation S4, the second insulating interlayer 130b may be formed on the second conductive pattern, the second alignment pattern 112 and the second test pattern T2.

In operation S5, a third conductive layer may be formed on the second insulating interlayer 130b. The third conductive layer may be patterned using a third mask to form a third conductive pattern in the die region 10. Simultaneously, the third alignment pattern 113 and the third test pattern T3 may be formed in the scribe lane SL. The third alignment pattern 113 may be formed at a region corresponding to a second window AP2 of the second alignment pattern 112. The third test pattern T3 may be electrically connected with the second test pattern T2. For example, the third conductive pattern may include a second wiring or a storage node electrode in the die region 10, not limited thereto.

In operation S6, the third insulating interlayer 130c may be formed on the third conductive pattern, the third alignment pattern 113 and the third test pattern T3.

In operation S7, a fourth conductive layer may be formed on the third insulating interlayer 130c. The fourth conductive layer may be patterned using a fourth mask to form a fourth conductive pattern in the die region 10. Simultaneously, the fourth alignment pattern 114 and the fourth test pattern T4 may be formed in the scribe lane SL. The fourth alignment pattern 114 may be formed at a region corresponding to a third window AP3 of the third alignment pattern 113. The fourth test pattern T4 may be electrically connected with the third test pattern T3. The fourth conductive pattern may include a third wiring, a power wiring or a plate electrode line of the integrated circuit. Thus, the alignment key 110a or 110b including the first to fourth alignment patterns 111-114 may be formed in the scribe lane SL. A test pattern group 120 including the first to fourth test patterns T1-T4 may also be formed in the scribe lane SL.

In operation S8, the fourth insulating interlayer 130d may be formed on the fourth conductive pattern, the fourth alignment pattern 114 and the fourth test pattern T4. The fourth insulating interlayer 130a may be planarized to expose a surface of the fourth alignment pattern 114 of the alignment key 110a or 110b.

The first alignment key 110a and the second alignment key 110b may have different structures or sizes to align the wafers using different type magnetic forces.

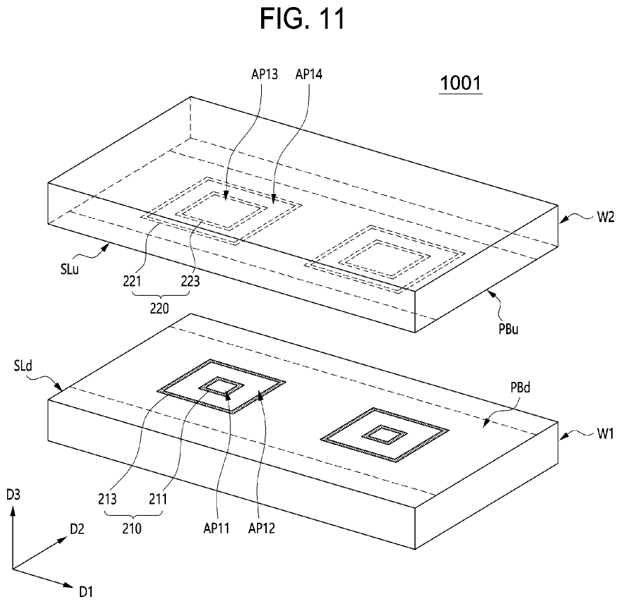

FIG. 11 is a perspective view illustrating wafers with an alignment key having different structures in accordance with various embodiments.

Referring to FIG. 11, a bonding structure 1001 of example embodiments may include a first wafer W1 and a second wafer W2. The first and second wafers W1 and W2 may include scribe lanes SLd and SLu, respectively, configured to define the dies 10 in FIG. 1.

For example, a plurality of first alignment keys 210 may be arranged in the scribe lane SLd of the first wafer W1. A plurality of second alignment keys 220 may be arranged in the scribe lane SLu of the second wafer W2. For example, the first and second alignment keys 210 and 220 may be arranged in a region where a pattern block PB of the scribe lanes SLd and SLu may be set.

In various embodiments, the first alignment key 210 may include a plurality of alignment patterns. The alignment patterns may have gradually changed sizes toward a facing surface. The alignment patterns of the first alignment key 210 may have a coil shape.

The second alignment key 220 may include a plurality of alignment patterns. The alignment patterns may have gradually changed sizes toward a facing surface. The alignment patterns of the second alignment key 220 may have a coil shape.

The alignment patterns of the first alignment key 210 and the alignment patterns of the second alignment key 220 may have different sizes. For example, when the first and second alignment keys 210 and 220 may be overlapped with each other, the alignment patterns of the second alignment key 220 may be positioned between the alignment patterns of the first alignment key 210.

In some embodiments, the first alignment key 210 may include a first alignment pattern 211 and a second alignment pattern 213. The first alignment pattern 211 may include a first window AP11 having a first size. The second alignment pattern 213 may be formed over the first alignment pattern 211. The second alignment pattern 213 may include a second window AP12 having a second size larger than the first size. The first alignment pattern 211 may be placed in the second window AP12 of the second alignment pattern 213.

The second alignment key 220 may include a first alignment pattern 221 and a second alignment pattern 223. The first alignment pattern 221 may include a third window AP13 having a third size different from the first and second sizes. For example, the third size may be larger than the first size and smaller than the second size. The second alignment pattern 223 may include a fourth window AP14 having a fourth size. The fourth size may be larger than the third size. The first alignment pattern 221 of the second alignment key 220 may be placed in the fourth window AP14 of the second alignment pattern 223.

When a wafer bonding process may be performed using the first and second alignment keys 210 and 220 having the different sizes, the first and second alignment keys 210 and 220 may receive a same voltage to generate a repulsive force, as detailed below.

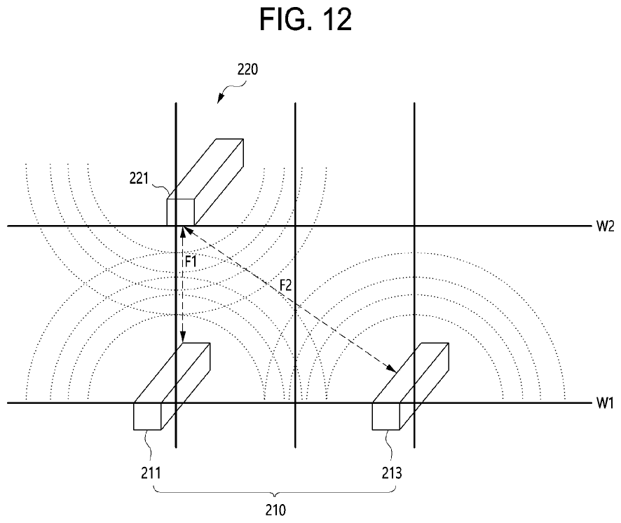

FIGS. 12 to 14 are cross-sectional views illustrating a method of bonding wafers using a repulsive force between alignment keys in accordance with other embodiments of the present disclosure. For conveniences of explanations, a bonding process between the first and second alignment patterns 211 and 213 of the first alignment key 210 and the first and second alignment patterns 221 and 223 of the second alignment key 220 may be illustrated.

Referring to FIG. 12, the first alignment pattern 211 and the second alignment pattern 213 of the first alignment key 210 may be electrified to a first polarity. Further, the first alignment pattern 221 and the second alignment pattern 223 of the second alignment key 220 may also be electrified to the first polarity.

The second wafer W2 may be placed over the first wafer W1 to face the first alignment key 210 and the second alignment key 220 to each other.

Because the first alignment key 210 and the second alignment key 220 may have the same polarity, a first repulsive force F1 may be generated between the first alignment pattern 211 of the first alignment key 210 and the first alignment pattern 221 of the second alignment key 220. Because the first alignment pattern 221 of the second alignment key 220 may be spaced apart from the second alignment pattern 213 of the first alignment key 210 farther than the first alignment pattern 211 of the first alignment key 210, a second repulsive force F2 smaller than the first repulsive force F1 may be generated between the second alignment pattern 213 of the first alignment key 210 and the first alignment pattern 221 of the second alignment key 220.

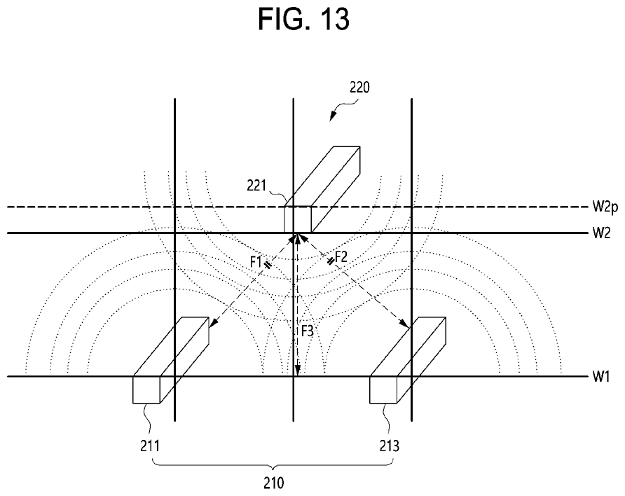

Thus, as shown in FIG. 13, the first alignment pattern 221 of the second alignment key 220 corresponding to the first alignment pattern 211 of the first alignment key 210 may be moved to one side by the first repulsive force F1 so that the first alignment pattern 221 of the second alignment key 220 may be shifted to a point between the first alignment pattern 211 and the second alignment pattern 213 of the first alignment key 210 where the first repulsive force F1 and the second repulsive force F2 may be offset.

The offset point of the first and second repulsive forces F1 and F2 may be a point where the first repulsive force F1 may be substantially the same as the second repulsive force F2, i.e., a minimum repulsive force section. A surface W2P of the second wafer W2 may be downwardly moved toward a surface of the first wafer W1 by the first and second repulsive forces W1 and W2.

A third repulsive force F3 applied between the first alignment pattern 221 of the second alignment key 220 and the first wafer W1 may be calculated based on the first and second repulsive forces F1 and F2 and a distance between the first alignment pattern 211 and the second alignment pattern 213 using a trigonometric function or various programs.

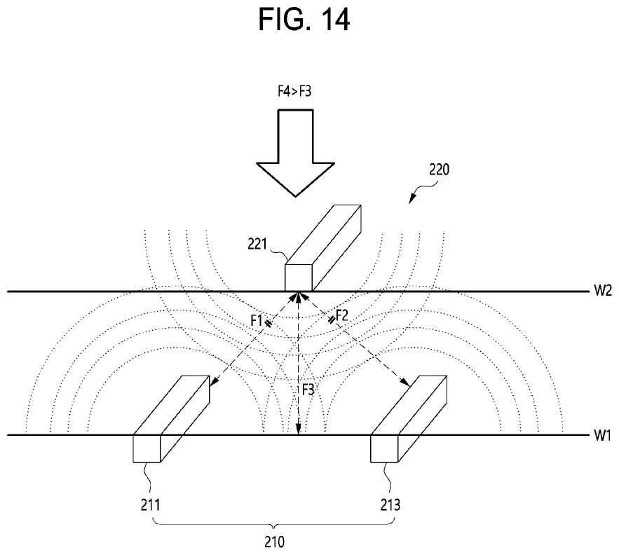

Referring to FIG. 14, a bonding force F4 may be applied to the second wafer W2 to perform the hybrid bonding process. The bonding force F4 may be higher than the third repulsive force F3 and lower than the first and second repulsive forces F1 and F2.

According to embodiments of the present disclosure, when the second alignment key 220 of the second wafer W2 is shifted to the minimum repulsive force section with respect to the first alignment key 210, the bonding pads of the first and second wafers W1 and W2 may be determined to be accurately aligned with each other.

Further, the alignment keys may receive the polarity by the various manners. For example, the alignment keys may be magnetized and bonded by a wafer bonding apparatus.

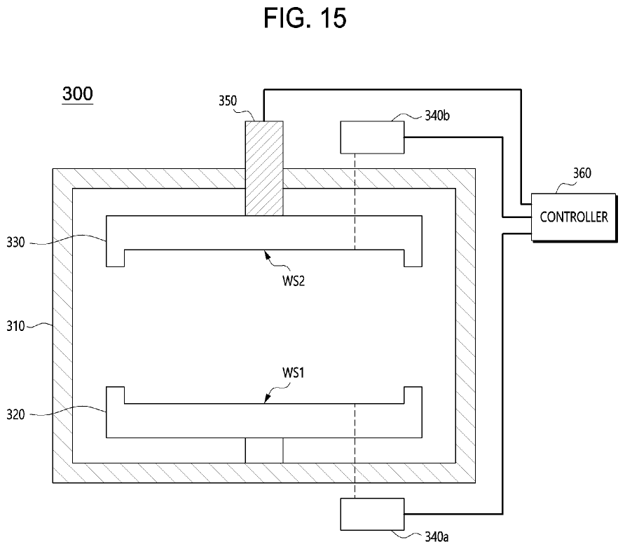

FIG. 15 is a cross-sectional view illustrating a wafer bonding apparatus in accordance with embodiments of the present disclosure.

Referring to FIG. 15, a wafer bonding apparatus 300 may include a chamber 310, a first bonding chuck 320, and a second bonding chuck 330.

The chamber 310 may include a housing configured to define a space where a wafer bonding process may be performed. The chamber 310 may be connected to a vacuum pump to provide an environment of the wafer bonding process.

The first bonding chuck 320 may be arranged at a lower space in the chamber 310. The first bonding chuck 320 may include a first wafer-holding surface WS1 facing the second bonding chuck 330. For example, the first wafer W1 may be fixed to the first wafer-holding surface WS1 using vacuum. The first bonding chuck 320 may include a ceramic.

The second bonding chuck 330 may be arranged at an upper space in the chamber 310. The second bonding chuck 330 may face the first bonding chuck 320 by a gap. The second bonding chuck 330 may include a second wafer-holding surface WS2 facing the first bonding chuck 320. For example, the second wafer W2 may be fixed to the second wafer-holding surface WS2 by the vacuum. The second bonding chuck 330 may include a ceramic.

A first voltage generator 340a may be electrically connected with the first wafer-holding surface WS1 to output selected portions of the first wafer-holding surface WS1 with any one of a reference voltage, a first voltage V1 and a second voltage V2.

The second voltage generator 340b may be electrically connected with the second wafer-holding surface WS2 to output selected portions of the second wafer-holding surface WS2 with any one of the reference voltage, the first voltage V1 and the second voltage V2.

The reference voltage may be an initial voltage, for example, ground voltage. For example, the first voltage V1 may be higher than the reference voltage to provide the alignment key(s) with the first polarity. The second voltage V2 may be lower than the reference voltage to provide the alignment key(s) with the second polarity opposite to the first polarity.

A bonding member 350 may pressurize a rear surface of the second bonding chuck 330 to physically bond the second wafer W2, which may be fixed to the first bonding chuck 320, to the first wafer W1.

A controller 360 may be directly and indirectly connected with the first voltage generator 340a, the second voltage generator 340b, the bonding member 350 and other elements of the wafer bonding apparatus. The controller 360 may determine an output voltage of the first voltage generator 340a and an output voltage of the second voltage generator 340b based on a shape of the alignment key of the wafers loaded into the wafer-holding surfaces WS1 and WS2. Further, the controller 360 may determine a bonding force of the bonding member 350 based on the shape of the alignment keys and the output voltages of the first and second voltage generators 340a and 340b. As mentioned above, the output voltages of the first and second voltage generators 340a and 340b may be a selected one of the reference voltage, a first voltage V1 and a second voltage V2. For example, the shape of the alignment key may determine the temporary magnetism of the alignment key, and the output voltages of the first and second voltage generators 340a and 340b may control the bonding force between the alignment keys together with the temporary magnetism.

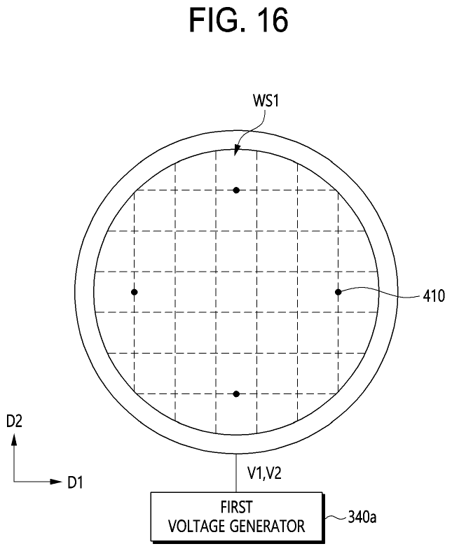

FIG. 16 is a plan view illustrating a wafer-holding surface in accordance with various embodiments. The first and second wafer-holding surfaces WS1 and WS2 may have a same structure. The first wafer-holding surface WS1 may be explained in reference to various embodiments herein.

Referring to FIG. 16, the wafer-holding surface WS1 may include at least one magnetic force generator 410. The magnetic force generator 410 may correspond to any one of the alignment keys of the wafer W1 or W2 to be fixed to the wafer-holding surface WS1 in one-to-one relation. A region indicated by a dotted line in FIG. 16 may correspond to a scribe lane.

In one example, the magnetic force generator 410 may be electrically connected with the first voltage generator 340a to selectively receive the reference voltage, the first voltage V1, and/or the second voltage V2 from the first voltage generator 340a. The magnetic force generator 410 may be directly and indirectly contacted with the selected alignment key. Thus, the selected alignment key may receive the output voltage of the first voltage generator 340a. As mentioned above, because the selected alignment keys may have the coil shape, when the alignment keys may receive the voltage V1 or V2, the induced current may be generated from the coil-shaped alignment keys so that the alignment keys may have a prescribed polarity.

The magnetic force generator 410 may be located at positions corresponding to n numbers of alignment keys (where n is a natural number of no less than 2) among the total alignment keys. That is, the n numbers of the magnetic force generators 410 corresponding to the n numbers of the alignment keys may be symmetrical with each other on the wafer-holding surfaces WS1 and WS2.

The wafer-holding surface WS1 may have a plurality of vacuum holes extended in a radial shape. The vacuum may be provided through the vacuum holes to fix the wafer to the wafer-holding surface WS1.

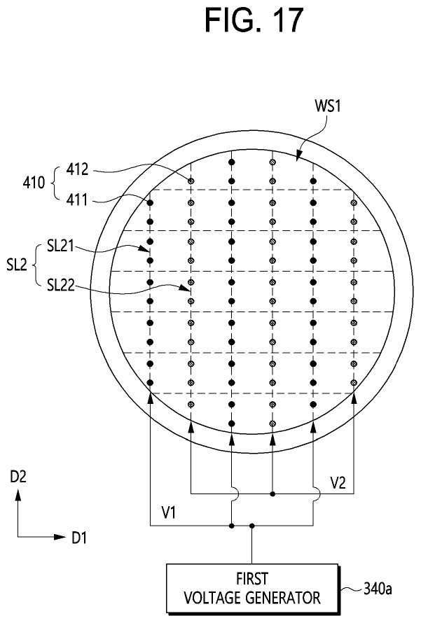

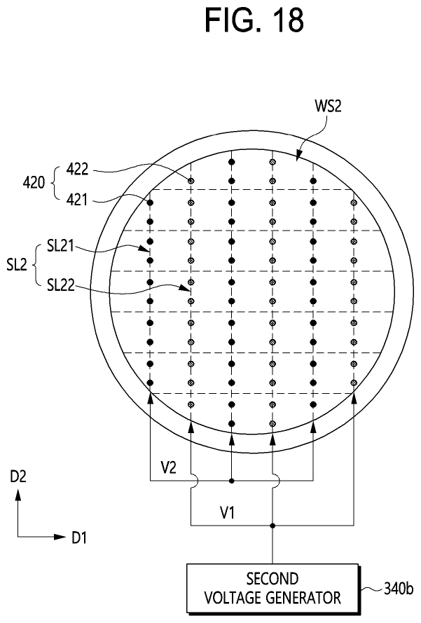

FIG. 17 is a plan view illustrating a first wafer-holding surface in accordance with embodiments of the present disclosure, and FIG. 18 is a plan view illustrating a second wafer-holding surface in accordance with example embodiments.

Referring to FIG. 17, the first wafer-holding surface WS1 may include a plurality of magnetic force generators 410. For example, the magnetic force generators 410 may be arranged at portions corresponding to the second line region SL2 in FIG. 2 extended in the second direction by a set rule or a set gap.

In some embodiments, the plurality of magnetic force generators 410 may include a plurality of odd magnetic force generators 411 and a plurality of even magnetic force generators 412.

The plurality of odd magnetic force generators 411 may be positioned at portions SL21 corresponding to odd second line regions SL2. The plurality of odd magnetic force generators 411 may receive the first voltage V1 from the first voltage generator 340a.

The plurality of even magnetic force generators 412 may be positioned at portions S22 corresponding to even second line regions SL22. The plurality of even magnetic force generators 412 may receive the second voltage V2 from the first voltage generator 340a.

For example, when magnetic force generators of the second wafer-holding surface WS2 have a structure substantially the same as a structure of the magnetic force generators 410 of the first wafer-holding surface WS1 to receive the voltage by a manner substantially the same as the manner of the first wafer-holding surface WS1, a repulsive force is generated between the first alignment key of the first wafer W1, which may be fixed to the first wafer-holding surface WS1, and the second alignment key of the second wafer W2, which may be fixed to the second wafer-holding surface WS2. Thus, the second alignment key is shifted to the minimum repulsive force section to complete the alignment process between the bonding pads of the first and second wafers W1 and W2.

Referring to FIG. 18, the second wafer-holding surface WS2 may include a plurality of magnetic force generators 420 so that the second wafer-holding surface WS2 may correspond to the first wafer-holding surface WS1. In embodiments of the present disclosure, the plurality of magnetic force generators 420 of the second wafer-holding surface WS2 may include a plurality of odd magnetic force generators 421 and a plurality of even magnetic force generators 422.

The odd magnetic force generators 421 may be positioned at portions SL22 corresponding to odd second line regions SL2. The odd magnetic force generators 421 may receive the second voltage V2 from the second voltage generator 340b. The even magnetic force generators 422 may be positioned at portions SL22 corresponding to even second line regions SL2. The even magnetic force generators 422 may receive the first voltage V1 from the second voltage generator 340b.

Accordingly when the magnetic force generators 420 of the second wafer-holding surface WS2 have a structure substantially the same as a structure of the magnetic force generators 410 of the first wafer-holding surface WS1, and the magnetic force generators 420 of the second wafer-holding surface WS2 receives the voltage by a manner different form the first wafer-holding surface WS1, an attractive force may be generated between the first alignment key of the first wafer W1, which may be fixed to the first wafer-holding surface WS1, and the second alignment key of the second wafer W2, which may be fixed to the second wafer-holding surface WS2.

Thus, the first and second alignment keys may be bonded to each other by the attractive force to complete the alignment process between the bonding pads of the first and second wafers W1 and W2.

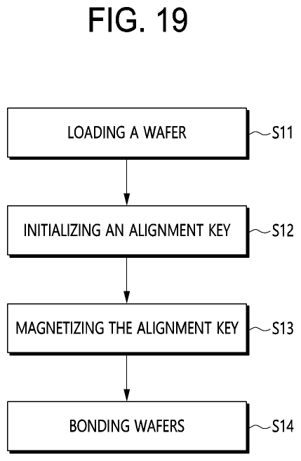

FIG. 19 is a flow chart illustrating a method of applying a magnetic force to an alignment key in accordance with embodiments of the present disclosure.

Referring to FIG. 19, in operation S11, the wafer W1 or W2 with the alignment key 110, 210 or 220 may be loaded into the wafer-holding surface WS1 or WS2 of the bonding chuck 320 or 330 using a transfer apparatus such as a robot arm.

The scribe lane SL of the wafer W1 or W2 may be aligned with a portion of the bonding chuck 320 or 330 corresponding to the scribe lane SL. Thus, the magnetic force 410 and the alignment key 110, 210 or 220 of the wafer-holding surface WS1 or WS2 may be contacted with each other.

In operation S12, the first or second voltage generator 340a or 340b may provide the magnetic force generator 410 with the reference voltage, for example, the ground voltage. Thus, the magnetic force generator 410 may apply the reference voltage to the alignment key 110, 210 or 220 making contact with the magnetic force generator 410 to initialize the alignment key 110, 210 or 22.

In operation S13, the voltage generator 340a or 340b may apply the first voltage V1 higher than the reference voltage or the second voltage V2 lower than the reference voltage to the alignment key 110, 210 or 220 through the magnetic force generator 410. Thus, the alignment key 110, 210 or 220 may be magnetized to the first polarity or the second polarity.

According to embodiments of the present disclosure, the bonding pads of the wafers may be accurately aligned with each other using the alignment keys temporarily magnetized by the induced current.

The alignment key of various embodiments of the present disclosure may be manufactured by previously used processes without an additional process. The alignment key may be temporarily magnetized by the induced current so that the electrical problem caused by the magnetism of the alignment key may not be generated in processes except for the bonding process.

Further, the alignment key of various embodiments of the present disclosure may have the planar frame shape, but the present invention is not limited thereto. For example, when the at least one surface of the alignment key may have the coil shape, the alignment key may have various planar shape such as a linear pattern shape or a hook shape.

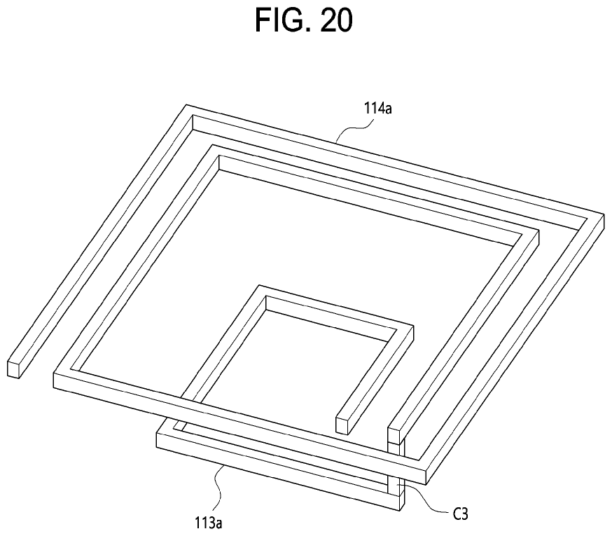

FIG. 20 is a perspective view illustrating an alignment key in accordance with other embodiments of the present disclosure.

Referring to FIG. 20, the coil-shaped alignment key may be formed using a conductive pattern 114a coplanar with the alignment key. Alternatively, coil-shaped conductive patterns 113a and 114a positioned on different planes may be combined with each other to form the coil-shaped alignment key.

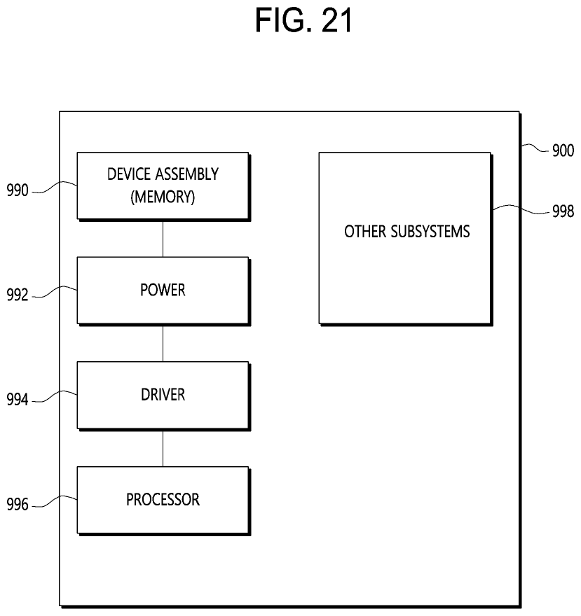

FIG. 21 is a schematic view of a system that includes a semiconductor die assembly configured in accordance with some embodiments of the present technology.

Any one of the semiconductor devices having the features described above with reference to FIGS. 1 to 14 can be incorporated into any of a myriad of larger and/or more complex systems, a representative example of which is system 900 shown schematically in FIG. 21. The system 900 may include a memory 990 substantially as described above (e.g., SRAM, DRAM, flash, and/or other memory devices), a power supply 992, a drive 994, a processor 996, and/or other subsystems or components 998. The semiconductor devices described above with reference to FIGS. 1 to 14 can be included in any of the elements shown in FIG. 21. For example, the memory 990 can be include a stack of wafers bonded in accordance with the hybrid bonding process described above with respect to FIG. 9.

The resulting system 900 can be configured to perform any of a wide variety of suitable computing, processing, storage, sensing, imaging, and/or other functions. Accordingly, representative examples of the system 900 include, without limitation, computers and/or other data processors, such as desktop computers, laptop computers, Internet appliances, hand-held devices (e.g., palm-top computers, wearable computers, cellular or mobile phones, personal digital assistants, music players, etc.), tablets, multi-processor systems, processor-based or programmable consumer electronics, network computers, and minicomputers. Additional representative examples of the system 900 include lights, cameras, vehicles, etc. With regard to these and other example, the system 900 can be housed in a single unit or distributed over multiple interconnected units, e.g., through a communication network. The components of the system 900 can accordingly include local and/or remote memory storage devices and any of a wide variety of suitable computer-readable media.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the present disclosure.

1. A bonding structure comprising:
a first wafer including first bonding pads;
a second wafer including second bonding pads configured to be hybrid bonded to the first bonding pads of the first wafer;
at least one first alignment key formed in the first wafer, the first alignment key configured to be magnetized by induced current flow in the first alignment key; and
at least one second alignment key formed in the second wafer, the second alignment key configured to generate a magnetic force with the first alignment key.

2. The bonding structure of claim 1, wherein at least one of the first and second wafers comprises a scribe lane configured to define a plurality of dies, and
wherein the first alignment key is positioned in the scribe lane of the first wafer, and the second alignment key is positioned in the scribe lane of the second wafer.

3. The bonding structure of claim 1, wherein
the first alignment key has a temporary magnetism induced by the current flowing therein; and
the second alignment key has a temporary magnetism induced by the current flowing therein.

4. The bonding structure of claim 3, wherein at least one of the first and second alignment keys comprises a plurality of stacked alignment patterns, and at least one of the alignment patterns has a coil shape formed together with adjacent alignment patterns in a stacked direction.

5. The bonding structure of claim 3, wherein the first and second alignment keys have a same structure.

6. The bonding structure of claim 5, wherein the first and second alignment keys have opposite polarities.

7. The bonding structure of claim 3, wherein the first and second alignment keys have different structures.

8. The bonding structure of claim 5, wherein the first and second alignment keys have a same polarity.

9. The bonding structure of claim 1, wherein at least one of the first and second alignment keys comprises:
a plurality of alignment patterns sequentially stacked;
a plurality of insulating interlayers interposed between the alignment patterns; and
at least one connection member connected between the alignment patterns to provide the alignment patterns with a coil shape.

10. The bonding structure of claim 9, wherein the alignment patterns have structures gradually changing in a stacked direction of the alignment patterns.

11. The bonding structure of claim 2, wherein the first wafer includes a plurality of first alignment keys and the second wafer includes a plurality of second alignment keys,
wherein the plurality of first alignment keys are arranged in the scribe lane of the first wafer in a rule, and the plurality of the second alignment keys are arranged in the scribe lane of the second wafer.

12. The bonding structure of claim 11, wherein n numbers of first alignment keys, where n is a natural number of no less than 2, among the first alignment keys and n numbers of second alignment keys among the second alignment keys have temporary magnetism.

13. The bonding structure of claim 12, wherein the n numbers of the first alignment keys are symmetrical with each other on the first wafer, and the n numbers of the second alignment keys are symmetrical with each other on the second wafer.

14-20. (canceled)

21. An electromagnetic alignment key for alignment of a first semiconductor device wafer with a second semiconductor device wafer, the alignment key comprising:
a plurality of alignment patterns sequentially stacked over each other and positioned on the first semiconductor device wafer;
a plurality of insulating interlayers interposed between the alignment patterns; and
at least one connection member connected between the alignment patterns to provide the alignment patterns with a coil shape,
wherein the electromagnetic alignment key has temporary magnetism, generated by current flow in the plurality of alignment patterns, which generates an electromotive force which induces motion of the first semiconductor device wafer relative to the second semiconductor device wafer.
